(19) United States
(12) Patent Application Publication
(10) Pub. No.: US 2025/0208370 A1
(43) Pub. Date: Jun. 26, 2025

(54) Vehicle Camera With Surface Heating

(71) Applicant: MEKRA Lang GmbH & Co. KG, Ergersheim (DE)

(72) Inventor: Bernhard SCHÖFER, Höchstadt a. d. Aisch (DE)

(73) Assignee: MEKRA Lang GmbH & Co. KG, Ergersheim (DE)

(21) Appl. No.: 18/983,949

(22) Filed: Dec. 17, 2024

(30) Foreign Application Priority Data
Dec. 22, 2023 (DE) 102023136644.0

(51) Int. Cl. G02B 7/02; G03B 17/12; G03B 17/55; G03B 30/00; H04N 23/51; H04N 23/55

(52) U.S. Cl. CPC G02B 7/028; G03B 17/12; G03B 17/55; G03B 30/00; H04N 23/51; H04N 23/55

(57) ABSTRACT

A camera (20) for a vehicle, in particular, a commercial vehicle, having a housing (22), at least one optical element (24) arranged in or at the housing (22), and a circuit board (10) with at least one image sensor (16) and a surface heating (17) for heating the optical element (24).

### BACKGROUND OF THE INVENTION

### 1. Field of the Invention

The present invention relates to a camera with a surface heating, in particular, a camera for a vehicle, e.g., a commercial vehicle.

### 2. Description of the Related Art

For some time, camera systems and image capture systems, respectively, are used with vehicles, in particular, commercial vehicles, as devices for indirect view beside conventional mirrors as devices for indirect view, either in addition or as replacement of these mirrors. The camera systems usually have an image capture unit, such as a camera which captures the vehicle surroundings continuously as (video) data. The (video) data captured by the image capture unit are transmitted to a reproduction unit which is located in a driver's cabin, if necessary, after processing, which reproduction unit displays the (video) data permanently and in real time to a driver and, if so, fades in additional information for the captured portion of the surroundings, such as collision hints, distances and the like.

The cameras of camera systems are usually mounted to an outer side of the vehicle. Accordingly, the cameras are subjected to any weather condition at the site of the vehicle. In particular, in case of low temperatures, the image capture function of the camera may be affected due to the formation of frost or condensation on the optical element and the cover glass of the optical element, respectively. Further, there is a risk that components which are repeatedly subjected to low temperatures suffer material changes and, thus, wear out more quickly.

In order to avoid the formation of frost or condensation on the optical element of a camera, it is known to heat the camera. So far, heating elements, e.g., in the form of discrete resistances, are arranged at specific positions on the circuit board, as it is disclosed in DE 10 2013 020 894 B3. However, these heating elements require a relatively large amount of installation space in the camera. Thereby, there is either a lack of installation space for other components in the camera or, if the other components are nevertheless installed, the camera in total becomes larger which leads to drawbacks on the required installation space in the vehicle.

### SUMMARY OF THE INVENTION

In view of this, it is an object of the present invention to provide a camera which on the one hand has a compact heating reliably counteracting a formation of frost or condensation and on the other hand requires a small installation space in the camera.

### SUMMARY

This object is solved by a camera with the features of claim 1 and a vehicle with the features of claim 18. Preferred embodiments are given in the dependent claims.

The invention is based on the idea to provide a camera for a vehicle, in particular, a commercial vehicle, with a surface heating. The surface heating is at least partly mounted/applied to the circuit board which also carries the image sensor. The surface heating is made of a heat-conducting material and extends over a certain area of the circuit board. An area means presently a geometric shape, specifically, a portion expanding flatly in length and width. In particular, the surface heating is defined in that its extension in length and width direction, respectively, is many times larger than its extension in thickness direction. In this respect, the extension of the surface heating in length and width direction is determined such that that they span a plane which, when arranged on the circuit board, is essentially parallel to the plane spanned by the length and width direction of the circuit board.

By a surface heating, the heat is continuously inputted into the optical element of the camera via a larger surface, as the heat emitting surface is larger than with conventional heating elements. At the same time, due to only a very small extension of the surface heating in the thickness direction of the surface heating, only a very small installation space is required in a longitudinal direction of the camera. The longitudinal direction of the camera is defined as the direction in which a plug, one or more circuit board(s) and an optical element of the camera are arranged in a row.

For example, the surface heating may be made of a thin sheet of metal which is glued on the circuit board. Alternatively, the surface heating may also be a thin metal layer which is sprayed, cast, vapor-deposited or galvanized onto the circuit board. However, preferably, the surface heating is formed by a conductor path. The conductor path may be made of copper material, aluminum or a copper alloy and an aluminum alloy, respectively. Alternatively, the conductor path may also be made of another heat-conducting material. In order to provide a surface heating, the conductor path is placed and laid, respectively, such that single sections of the conductor path or, in the case of multiple conductor paths, the single conductor paths are arranged next and adjacent to each other on the circuit board. Adjacent to each other means presently that no other element is present between the single sections of the conductor path(s), however, the single sections do not contact each other. For example, the conductor path may be placed in a meandering manner. In a meandering manner presently means that the conductor path is placed in loops and windings, respectively, and changes direction by approximately 180 degrees at each of two predefined end positions. So, the conductor path has several conductor path sections which run approximately parallel to each other without any interruption. A meandering arrangement has the advantage that—in contrast to a spiral arrangement of the conductor path—the conductor path does not act as an antenna and, thus, neither the electronic of the camera nor neighboring devices are interfered by emitted interference radiation and so the electromagnetic compatibility is ensured.

The heating power of the surface heating which is formed by a conductor path is based on the cross section and the length of the conductor path as well as on its arrangement which is referred to as the geometry of the surface heating in the following. Via the specific thermal conductivity of the material used for the conductor path as well as the cross section of the conductor path, a resistance can be generated. Thus, a resistance may be calculated for a predetermined current or voltage as well as a predetermined heating power which can in turn be transferred into a suitable conductor path geometry.

For effectively heating the optical element, it is preferred that the conductor path extends partly around the image sensor. Alternatively, the conductor path may also encompass the image sensor completely.

Since the heating of the camera primarily serves for avoiding formation of frost or condensation, it is advantageous, if the conductor path is arranged on the side of the circuit board on which the image sensor is arranged and which, accordingly, faces the optical element. Alternatively, the conductor path may also be arranged on the side which is opposed to the optical element, or a conductor path can be arranged on both sides of the circuit board.

According to a preferred embodiment, the boundary around the outside (outer boundary) of the conductor path arranged in a plane substantially corresponds to the outer dimension of the optical element. So, an efficient heat input into the optical element can be ensured.

Preferably, the conductor path is arranged on a specific circuit board layer, further preferably on the circuit board layer on which also the image sensor is arranged. Alternatively, the conductor path can also be arranged on another, for example internal circuit board layer, or on a circuit board layer on the side of the circuit board which is opposed to the side with the image sensor. By the fact that the conductor path is arranged on only one circuit board layer, the conductor path has further preferably a substantial two-dimensional planar shape wherein the conductor path has an extension in a length and width direction, but nearly no extension in a thickness direction.

Further alternatively, the conductor path can extend across a plurality substantially parallel circuit board layers. This means that the conductor path is arranged such that it has, in a top view of the circuit board, a flat arrangement of adjacent conductor path sections or conductor paths, but in a sectional view of the circuit board switches between different parallel circuit board layers. In other words, in a cut through the circuit board, conductor paths are present on a plurality of circuit board layers which change and switch, respectively, between the circuit board layers. Thus, the term “surface heating” also has to be understood as an arrangement whose single sections are configured flatly and, thus, only have a very limited extension in the thickness direction of the conductor path, in total, however, have no flat configuration in a sectional or side view, but have a configuration which is at different height levels in the direction of the thickness of the circuit board while maintaining a dimension that extends only very slightly in the direction of the thickness.

In order to avoid a heating of the image sensor and, thus, image noise, the circuit board layer on which the image sensor is arranged can be removed and kept clear, respectively, between image sensor and conductor path. This means that between the image sensor and the conductor path no heat-conducting material is present. So, it can be avoided that the heat of the conductor path is transmitted to the image sensor which in turn promotes a reliable function of the image sensor. This effect can be amplified if the space exposed from heat-conducting material is filled with a heat-insulating material. Alternatively or in addition to removing the circuit board layer, a thermal barrier can be provided between the image sensor and the conductor path. The thermal barrier can either be made of a heat-insulating material and may serve for heat insulation or may be made of a heat-conducting material, e.g., the material of the conductor path, and may serve as heat storage and heat buffer, respectively. In order to store and buffer, respectively, sufficient heat, the thermal barrier has a certain thermal capacity. The term of thermal capacity presently means the ability to receive and store heat. For example, the thermal barrier may be configured as a circle and ring, respectively, with a certain extension in the longitudinal direction of the camera and the thickness direction of the conductor path such that the thermal barrier has a certain accumulation of material for storage of heat energy.

Preferably, the camera comprises at least one second conductor path for selective controlling depending on heating power requirements. For example, the camera may have two conductor paths which are configured as described above and which may be arranged either concentrically to each other or next to each other around the image sensor. During operation of the heating, one of the two conductor paths may only be switched on in addition to the other conductor path, if a higher heating power is required such as this is the case at temperatures below the freezing point. Alternatively or additionally to the adaptation of the heating power, the cross section of the conductor path may vary along the extension of the conductor path. For example, the conductor path may have a continuously varying cross-section or may also vary only in sections with respect to the cross-section.

For fixing the optical element in or at the housing of the camera, a heat-conducting element may be provided between the optical element and the housing. Preferably, the heat-conducting element is made of a potting compound which fixes the optical element in the housing and is made of a heat-conducting material. So, the heat of the conductor path may not only be introduced directly into the optical element, but also via the potting compound indirectly into the optical element by introducing the heat firstly into the housing of the camera and then via the housing of the camera into the optical element. In this manner, an even more efficient and quicker heating of the optical element can be promoted.

Alternatively or additionally, the optical element may be fixed on the circuit board by means of an adhesive. The adhesive is preferably made of a heat-conducting material such that a reliable heat transfer from the conductor path to the optical element occurs.

Preferably, the camera comprises at least one temperature sensor for adaptation of the heating capacity and/or for adaptation of the heating time. The temperature sensor serves for detecting temperature statuses inside the housing of the camera and/or at the optical element which temperature statuses require either an adaptation of the heating power and/or an adaptation of the heating time. For this purpose, the sensor is preferably arranged inside the housing of the camera, e.g., embedded in the potting compound and/or the adhesive, preferably at or near the optical element. If the temperature sensor detects, e.g., that the temperature inside the camera housing has exceeded a particular, predetermined value, this result may be transmitted via a central electronic control unit (ECU) to a regulating unit which in turn reduces or switches off the heating power. The other way round, the regulating unit may also switch on or increase the heating power, if the temperature sensor detects that the temperature inside the camera housing has fallen below a predetermined temperature threshold. The monitoring of the temperature inside the camera housing may additionally or alternatively also be initiated by a user, e.g., the driver of the vehicle. For this, a user interface/a user knob, such as a user interface with an ON/OFF switch, may be provided inside the vehicle by use of which the user may start or stop the operation of the surface heating. Alternatively or additionally, a controlling of the temperature inside the camera housing may also occur by means of predefinition of a heating time.

In principle, the operation of the surface heating may occur via the ECU in connection with a regulating unit in that temperature sensors detect and report temperature values and, in case of exceeding or falling below specified temperature values, the surface heating is operated or no longer operated. Alternatively or additionally, the surface heating may also be operated by a user, e.g., by means of certain operating elements provided for this purpose in a passenger compartment of the vehicle, if he does not receive sufficiently good camera images when it is cold outside and, therefore, there is either formation of condensation or frost.

Additionally or alternatively to the at least one temperature sensor, a current sensor may be provided which detects the current strength in the conductor path and adapts the heating power and, if so, heating time via a regulating unit, if a current strength in the conductor path exceeds a permissible value or falls below a required value. The current sensor may be provided in the thermal barrier or on the circuit board. Here too, a manual setting of the heating power and the heating time may be performed by a user depending on the present current strength. For this, the user is informed about the present current strength and may adapt it accordingly, wherein the user input may be overridden by the control unit in case of a detrimental adaptation of the heating by the user, in order to avoid a damage of the surface heating and the camera.

The at least one conductor path is preferably not only used for heating the optical element, but is also used as a power supply line for components located on the circuit board, such as the image sensor. By the simultaneous usage of the conductor path as supply line, a drop of voltage occurs which has to be considered when designing the conductor path.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the following, the invention is described by way of example with reference to the attached figures, in which:

FIG. 1 shows a longitudinal section through a camera according to the invention with a surface heating according to a first embodiment,

FIG. 2 shows a perspective view of a circuit board with conductor path and optical element,

FIG. 3 shows a top view of a circuit board with conductor path, image sensor and thermal barrier, and

FIG. 4 shows a perspective view of a circuit board with a surface heating according to a second embodiment.

### DETAILED DESCRIPTION OF THE PRESENTLY PREFERRED EMBODIMENTS

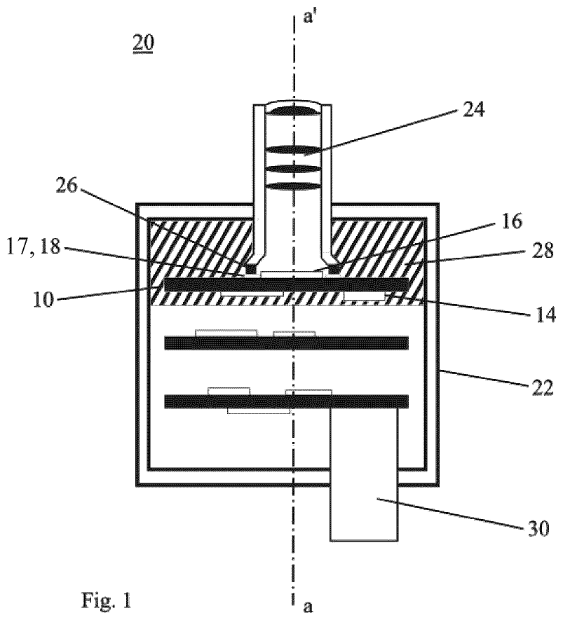

FIG. 1 shows a longitudinal section through a camera 20 for a vehicle which has a middle axis a-a′. The camera 20 has a housing 22. Inside the camera 22, an optical element 24 and a plurality of circuit boards 10 are arranged. The optical element 24 consists of an objective/lens and a cover glass for protection of the lens. On the circuit board 10 next to the optical element 24, on the side which faces the optical element 24, an image sensor 16 for recording images of a surroundings around the vehicle is arranged in the middle thereof. On the opposite side, i.e., the side of the circuit board 10 which faces away from the optical element 24, electric components are arranged which are required for performing a camera function. The electric components 14 may, alternatively or additionally, be arranged on the side of the circuit board 10 which faces the optical element 24. The circuit board which is located furthest away from the optical element 24 is provided with a connector 30 for voltage supply of the camera and for data transmission. The circuit boards are connected with each other in a conductive manner (not shown). The direction along the longitudinal axis a-a′ in which the circuit boards, the image sensor 16 and the optical element 24 are arranged one after the other, is presently referred to as the longitudinal direction.

Around the image sensor 16, i.e., on the side of the circuit board 10 which faces the optical element 24, a surface heating 17 which is configured/formed as a conductor path 18 is provided. The outer dimensions of the conductor path 18 substantially correspond to the outer dimensions of the surface of the optical element 24 which faces the circuit board 10.

The optical element 24 is connected to the housing 22 and the circuit board 10 by means of a potting compound 28. The potting compound 28 is made of a heat-conducting material such as on a polyurethane base.

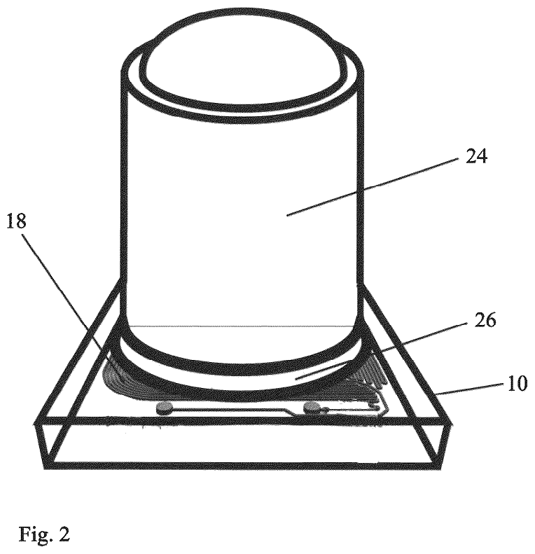

FIG. 2 shows a perspective view of the circuit board 10 with the optical element 24. As it is shown in FIG. 2, an end surface of the optical element 24 which faces the circuit board 10 is connected to the circuit board 10, specifically to the conductor path 18, by means of an adhesive 26, such as a superglue, a two-component adhesive, and the like. Just like the potting compound 28, the adhesive 26 is made of a heat-conducting material. As may be further seen in FIG. 2, the conductor path 18 is arranged in a meandering manner around the image sensor 16 (not shown in FIG. 2), wherein the particular windings and conductor path sections, respectively, change their running direction by about 180 degrees at a certain position with respect to the image sensor 16.

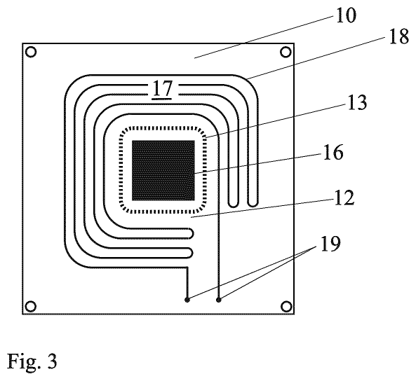

FIG. 3 shows a top view of the circuit board 10 of FIG. 1. As shown in FIG. 3, the image sensor 16 is arranged approximately in the middle of the circuit board 16. The position of the image sensor 16 on the circuit board 10, may, however, also be located off-centered and, in principle, always has to be selected such that the optical element 24 can at least partially display and record, respectively, images of the vehicle surroundings on the image sensor 16. That means that it is not required, however possible, that the optical element 24 is exactly arranged above the image sensor 16. Around the image sensor 16, the conductor path 18 is arranged. The conductor path 18 is arranged in a meandering manner around the image sensor 16, in order to avoid an antenna effect of the conductor path 18. The terminal ends 19 of the conductor path 18 are also provided on circuit board 10 and are conductively connected with a power source (not shown). The image sensor 16 and the conductor path 18 are applied and provided, respectively, on a circuit board layer 12. The circuit board layer 12 is made of a heat-conducting metal, such as copper, and forms a copper layer.

Between the image sensor 16 and conductor path 18, a thermal barrier 131 is provided. The thermal barrier 13 is configured as a closed fence, e.g., as a ring, and encompasses the image sensor 16 completely. The thermal barrier 13 may be made of a heat-insulating material or may be made of metal, such as the same metal as the circuit board layer 12. Alternatively or additionally to the thermal barrier 13, the circuit board layer 12 between image sensor 16 and conductor path 18 may also be omitted. So—if so, in addition to the thermal barrier 13—it is avoided that the heat of the conductor path 18 is transmitted to the image sensor 16 via the circuit board layer 12.

For heating the camera 20, the conductor path 18 is energized which results in that the conductor path 18 is heated. By the spatial vicinity of the conductor path 18 to the optical element 24, the heat of the conductor path 18 is transmitted by thermal convection via the air to the optical element 24. In addition, the heat energy of the conductor path 18 is transmitted via the heat-conductive adhesive 26 directly, i.e., from the conductor path 18 without any further element than the adhesive 26, to the optical element 24. In addition, the heat of the conductor path 18 is also transmitted from the heat-conductive potting compound 28 to the housing 22 and from the housing 22 via thermal convection via the air to the optical element. So, the formation of frost or condensation on the optical element can be avoided or an already formed frost layer or condensation can be removed.

It is conceivable that the strength or voltage of the current flowing through the conductor varies depending on the intended heating power. In addition or alternatively, it is conceivable for varying the heating power that not only one conductor path 18, but a plurality of conductor paths 18 are provided on the circuit board 10 which may be operated individually or jointly. Also, it is conceivable that the conductor path 18 does not have the same cross-section along its entire extension, but that the cross-section may vary. For example, the conductor path 18 may have a continuously varying cross-section or may also vary only in sections as regards the cross-section. Generally speaking, the smaller the cross-section and the longer the conductor path, the higher is the resistance and vice versa. So, a cross-section and a length of the conductor path 18 may be calculated based on a desired heating power and a specified current strength or voltage as well as the specific thermal conductivity of the selected material for the conductor path 18.

The thermal barrier 13 acts as a kind of protection ring for avoiding that the heat of the conductor path 18 is transmitted to the image sensor 16. Either the thermal barrier 13 avoids a heat transmission to the image sensor 16 by being made of a heat-insulating material and insulates the image sensor 16 from the conductor path 18. Or the thermal barrier 13 is made of a heat-conductive material and stores the heart of the conductor path 18 such that the heat is not transmitted to the image sensor 16 or is not transmitted thereto until a certain time. This effect of heat insulation is further supported by omitting and keeping clear, respectively, the circuit board layer 12 between the image sensor 16 and the conductor path 18. Omitting the circuit board layer 12 between the image sensor 16 and the conductor path 18 may also be the single measure (i.e., without providing a thermal barrier 13) for heat insulation of the image sensor 16.

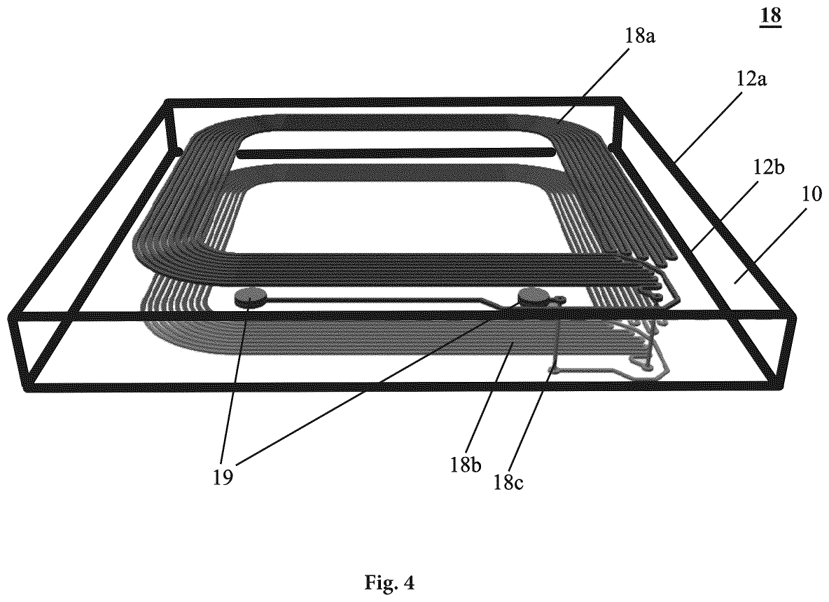

FIG. 4 shows a perspective view of a circuit board 10, wherein the conductor path 18 is not only arranged on a circuit board layer 12, but wherein the conductor path 18 extends across a plurality of circuit board layers.

The surface heating 17 which is configured as conductor path 18 in the embodiment shown in FIG. 4 is substantially formed of two conductor path portions 18a and 18b. The first conductor path portion 18a runs on a first circuit board layer 12a, whereas the second conductor path portion 18b runs on a second circuit board layer 12b which is substantially parallel to the first circuit board layer (not shown). Both conductor paths 18a and 18b are conductively connected with each other via a conductor path web 18c. As the conductor path web 18c establishes a contact between the first conductor path portion 18a which is located on the first circuit board layer 12a and the second conductor path portion 18b which is located on the further circuit board layer 12b, the conductor path web 18c extends in a further spatial direction and the conductor path 18 is configured three-dimensionally at the position of the conductor path web 18c. In principle, however, the conductor path 18 by means of the conductor paths 18a and 18b is mainly and, thus, via wide sections configured two-dimensionally.

Even though FIG. 4 shows an essentially exact overlap and identical formation, respectively, of the two conductor path portions 18a and 18b, it is possible that the conductor path portions 18a and 18b are indeed formed identically in terms of their planar extension, but are arranged offset in the transverse direction to the longitudinal direction of the camera. Alternatively or additionally, it is also conceivable that the conductor path portions 18a, 18b are formed differently to each other as regards their planar extension. For example, it is conceivable that the conductor path portion 18a which is located closer to the optical element 24 has a larger extension as regards its planar extension than the conductor path portion 18b which is located farther away from the optical element 24 as compared to the conductor path portion 18a. Cross-section and material of the conductor path portions 18a, 18b may also differ. A suitable change of the cross-section and/or the material would be at the conductor path web 18c, but it can also occur at any other position on the conductor path portions 18a and 18b.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A camera for a vehicle, in particular, a commercial vehicle, comprising:
a housing,
at least one optical element arranged in or at the housing, and
a circuit board with at least one image sensor and a surface heating for heating the optical element.

2. The camera according to claim 1, wherein the surface heating is formed from at least one conductor path, wherein conductor path sections of the conductor path are arranged on the circuit board for forming a planar arrangement.

3. The camera according to claim, wherein the conductor path is arranged in a meandering manner.

4. The camera according to claim 2, wherein the conductor path is arranged at least partly around the image sensor.

5. The camera according to claim 2, wherein the conductor path is arranged on the side of the circuit board which faces the optical element.

6. The camera according to claim 2, wherein the outer boundary of the conductor path on the circuit board substantially corresponds to the outer boundary of the surface of the optical element which faces the conductor path.

7. The camera according to claim 2, wherein the conductor path is arranged on a certain conductor path layer of the circuit board.

8. The camera according to claim 7, wherein the conductor path has a substantial two-dimensional shape.

9. The camera according to claim 2, wherein the conductor path extends across a plurality of circuit board layers which are substantially parallel to each other.

10. The camera according to claim 9, wherein the conductor path has a three-dimensional shape.

11. The camera according to claim 5, wherein the circuit board layer is kept clear in an area between the image sensor and the conductor path.

12. The camera according to claim 2, wherein a thermal barrier is provided between the image sensor and the conductor path.

13. The camera according to claim 12, wherein the thermal barrier is made of a heat-conductive material and is configured such that it has a thermal capacity.

14. The camera according to claim 2, comprising at least a second conductor path for selective controlling depending on the heating power requirements.

15. The camera according to claim 1, further comprising a heat-conductive potting compound which is arranged between the circuit board, the housing and the optical element.

16. The camera according to claim 1, further comprising at least a temperature sensor for detection of a temperature inside the housing for adaptation of the heating power and/or for adaptation of the heating time.

17. The camera according to claim 2, wherein the at least one conductor path is adapted for being used as a as a power supply line for the image sensor and/or further components on the circuit board layer.

18. A vehicle with a camera according to claim 1.
